(19) United States
(12) Patent Application Publication
(10) Pub. No.: US 2025/0055429 A1
(43) Pub. Date: Feb. 13, 2025

(54) METHODS AND APPARATUS TO REJECT CURRENT RIPPLE

(71) Applicant: Texas Instruments Incorporated, Dallas, TX (US)

(72) Inventor: Yuhong Lu, Tempe, AZ (US)

(21) Appl. No.: 18/428,982

(22) Filed: Jan. 31, 2024

Related U.S. Application Data
(60) Provisional application No. 63/531,051, filed on Aug. 7, 2023.

(51) Int. Cl. H03F 3/45; H03F 1/26

(52) U.S. Cl. CPC H03F 3/45475; H03F 1/26; H03F 3/45273; H03F 2200/261; H03F 2200/459; H03F 2200/462

(57) ABSTRACT

An example apparatus includes: a low-pass filter and a high-pass filter coupled to a first current terminal of the first transistor; an input of a first amplifier coupled to the output of the high-pass filter; an input of a negative gain amplifier coupled to an output of the first amplifier; inputs of an adder coupled to an output of the negative gain amplifier and an output of the low-pass filter; a first input of a second amplifier coupled to the output of the adder; a control terminal of a second transistor coupled to the output of the second amplifier, a second current terminal of the second transistor coupled to the first input of the second amplifier; and a control terminal of a third transistor coupled to the output of the second amplifier, a second current terminal of the third transistor coupled to an output terminal.

### CROSS-REFERENCE TO RELATED APPLICATION

This patent claims the benefit of U.S. Provisional Patent Application No. 63/531,051, which was filed on Aug. 7, 2023. U.S. Provisional Patent Application No. 63/531,051 is hereby incorporated herein by reference in its entirety. Priority to U.S. Provisional Patent Application No. 63/531,051 is hereby claimed.

### TECHNICAL FIELD

This description relates generally to circuits and, more particularly, to methods and apparatus to reject current ripple.

### BACKGROUND

Power supplies provide electrical energy to electronic devices. Improvements in power supplies are directed toward providing electrical energy with greater stability and reliability. Ripple currents, which are AC currents flowing through load components that result in small fluctuations in direct current (DC) voltage output, are common phenomena in power supplies. The variations in the DC voltage output often result from switching or rectification processes within the power supply. Fluctuations in the DC voltage output can impact the performance of downstream, connected electronic components, or loads.

The ripple current, also referred to as current ripple, results from alternating current (AC) power sources and is a periodic waveform characterized by a narrow bandwidth pulse with a high amplitude. Accordingly, it can be said that the ripple current is the AC current component that “rides on top” (e.g., is superimposed) of a DC current waveform. The current ripple introduced to the downstream electronic components connected to a power supply is a periodic noise that is due to the switching frequency in switching power supplies. The downstream electronic components use various methods to take the useable power from the power supply and process the varying voltage or current (e.g., the signal) further using filters, amplifiers, and other modifiers, but the current ripple gets transmitted from the power supply to the electronic circuit attached to the power supply. Thus, circuits integrate components, such as capacitors, resistors, or metal-oxide-semiconductor field effect transistors (MOSFETs), to “reject” the ripple. Accordingly, ripple rejection is the ability of a circuit to maintain an output voltage despite ripple fluctuations in the power supply.

A power supply rejection ratio (PSRR) is the ratio of the change in supply voltage to the output voltage produced, and is a measure of how well a circuit rejects ripple coming from a power supply. In the case of a low dropout regulator (LDO), PSRR is a measure of the output ripple voltage compared to the input ripple voltage over a wide frequency range (e.g., 10 Hz to 10 MHz).

### SUMMARY

For methods and apparatus to reject current ripple, an example apparatus includes a first transistor having a first current terminal, a control terminal, and a second current terminal, the second current terminal of the first transistor coupled to a ground terminal; a low-pass filter having an input and an output, the input of the low-pass filter coupled to the first current terminal of the first transistor; a high-pass filter having an input and an output, the input of the high-pass filter coupled to the first current terminal of the first transistor; a first amplifier having an input and an output, the input of the first amplifier coupled to the output of the high-pass filter; a negative gain amplifier having an input and an output, the input of the negative gain amplifier coupled to the output of the first amplifier; an adder having a first input, a second input, and an output, the first input of the adder coupled to the output of the negative gain amplifier, the second input coupled to the output of the low-pass filter; a second amplifier having a first input, a second input and an output, the first input coupled to the output of the adder; a second transistor having a first current terminal, a control terminal, and a second current terminal, the control terminal of the second transistor coupled to the output of the second amplifier, the second current terminal of the second transistor coupled to the first input of the second amplifier; and a third transistor having a first current terminal, a control terminal, and a second current terminal, the control terminal of the third transistor coupled to the output of the second amplifier, the second current terminal of the third transistor coupled to an output terminal.

### BRIEF DESCRIPTION OF THE DRAWINGS

FIG. 1 is a block diagram showing power supply circuitry coupled to a processor.

FIG. 2 is a block diagram of an example low dropout (LDO) regulator of the power supply of FIG. 1, the LDO regulator including feed-forward current ripple rejection (FFCRR) circuitry.

FIG. 3 is a block diagram of an example LDO, including an example of FFCRR circuitry.

FIG. 4 is a flowchart demonstrating the functionality of the example FFCRR circuitry.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

Examples described herein may be used to implement paralleled feed-forward current ripple rejection (FFCRR) circuitry that counteracts the current ripple generated by a pass transistor in a low dropout regulator circuit. FFCRR circuitry is used in conjunction with a reference voltage, an amplifier, and a pass element of an LDO. For example, a pass element of an LDO circuit generates a current ripple. The FFCRR circuit senses the current flow through the pass element, modifies the sensed current, and injects the modified current to the voltage output in order to counteract the current ripple generated by the pass element. The FFCRR may be implemented as integral to an LDO or may be a feed forward current ripple rejection circuit that is attached to an existing LDO circuit.

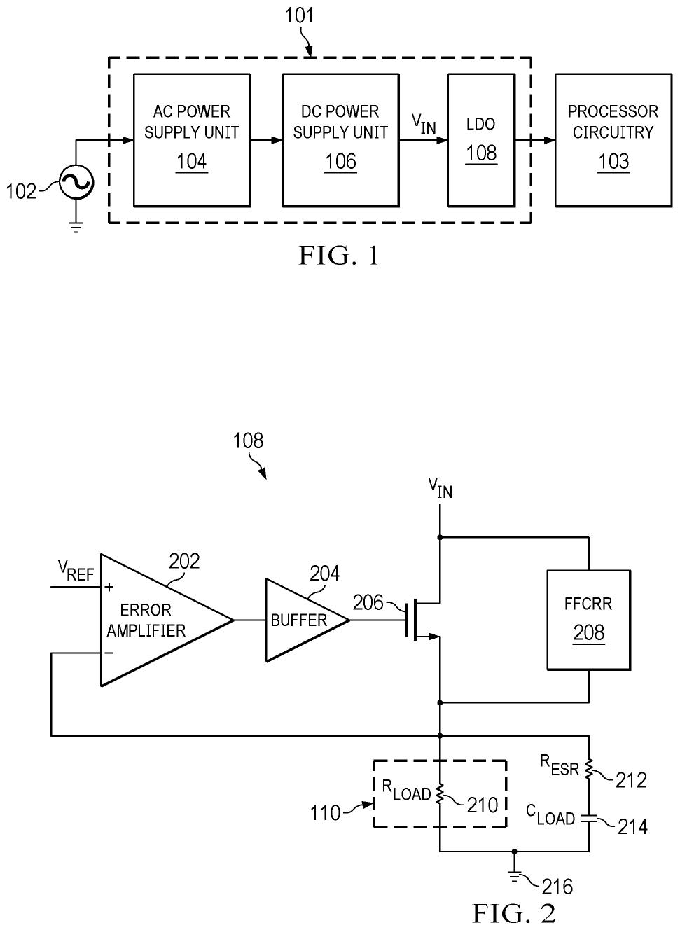

FIG. 1 is a block diagram of example power supply circuitry 101 coupled to a mains power supply 102 and providing power to a load 103, which is shown in the example of FIG. 1 as processor circuitry. The power supply circuitry 101 includes an AC power supply unit 104, a DC power supply unit 106, and a low dropout regulator 108.

FIG. 1 demonstrates the connections of the block diagram components. The mains power supply 102 is coupled to an AC power supply unit 104. The AC power supply unit 104 has its output coupled to a DC power supply unit 106. The DC power supply unit 106 has its output, Vin, coupled to supply the Vin output to an LDO circuit 108. The LDO circuit 108 is connected to a processor circuitry 103 as a load.

Mains power supply 102 indicates electrical power generation or connection to a power grid that is the primary source of electricity. Mains power is generated at power plants and delivered through a network of power lines and transformers. The voltage and frequency of mains power vary globally and are regionally dependent (e.g., 120 volts at 60 hertz). Mains power supports electrical technologies that depend upon power. Electricity is supplied by the mains power supply 102 in alternating current form, as the alternating nature of the current allows for efficient transmission over distances and facilitates the transmission of voltage through transformers.

The AC power supply 104 connected to the mains power supply 102 receives power from the main power grid in an alternating current form. The AC power supply 104 converts the incoming electrical energy to useable voltage and current levels for connected devices. For example, the AC power supply 104 steps down an incoming mains power supply voltage to a voltage suitable to be utilized by the DC power supply 106. An example output from an example AC power supply would be a 1 kHz sine wave being provided by an AC signal generator (the AC power supply 104) to a 5V DC power supply (the DC power supply 106).

Depending on the application, different devices and applications have varying requirements for the type of electrical current used. Accordingly, the DC power supply 106 is used to convert incoming, useable AC power to useable DC power. The DC power supply 106 is used to power electronic devices that require a steady voltage (e.g., the DC power supply 106 provides 5V DC). This is achieved by incorporating components such as rectifiers, filters, and regulators to provide such steady, consistent, and reliable voltage.

The LDO 108, or low dropout regulator is a type of voltage regulator used in electronic circuits. When connected to the DC power supply 106, the LDO regulates the output voltage (Vout) with “low dropout”, meaning the LDO can provide a stable output (Vout) even when the input voltage (Vin) is only slightly higher than the desired output voltage. The LDO 108 accomplishes this by using a feedback loop to adjust the output voltage and maintain a consistent output. Accordingly, LDOs are used where steady and reliable voltage is necessary for the proper operation of electronic circuits. LDOs include a reference voltage, an amplifier, and a pass element.

The representation of load 103 is shown as a processor in FIG. 1 and is used for illustrative purposes only. Processor circuitry 103 could represent any electrical load or device within the broader category of electronic components or devices. The depiction serves as a generic example to illustrate an electronic load and the specific identity or function could vary. Specifications associated with an LDO are determined based on the electronic load to be used in conjunction with the LDO. The electronic load is connected to an LDO, as shown in FIG. 1.

In operation, the mains power supply 102 provides AC power to the AC power supply 104. The AC power supply 102 transforms the input AC power from the mains power supply 102 to an AC power of a specific voltage, frequency, current and form demanded by an attached downstream component (e.g., a DC power supply). In the diagram of FIG. 1, the AC power supply unit 104 supplies the voltage frequency, current, and form to a DC power supply unit 106.

The DC power supply unit 106 transforms the alternating current into a stable DC voltage, Vin. The Vin can then be used to power different electrical devices, such as the LDO 108 of FIG. 1.

With Vin supplied to the LDO 108 of FIG. 1, the LDO regulates the input voltage, Vin, so that an output voltage, Vout, is attained. The output voltage, Vout, is supplied to the load 103. In the example of FIG. 1, processor circuitry is the load 103. Vout from the LDO circuit 108 powers the load 103 (e.g., processor circuitry) for operations.

Processor circuitry is one load that benefits from the ripple rejection scheme set forth by the implementation of a feed-forward current ripple rejection (FFCRR) circuit in conjunction with an LDO. Of course, other loads, as described herein, may be used instead of processor circuitry.

FIG. 2 is a circuit diagram of the LDO 108 of FIG. 1. In the example of FIG. 2, the LDO 108 includes an error amplifier 202, a buffer 204, a pass element 206, and an FFCRR circuit 208. Also included is the load 103, which may be processor circuitry, represented by Rload 210. To dampen the resonance within the circuit (e.g., stabilize the response of the circuit by storing energy), an equivalent series resistance resistor (RESR) 212 and a load capacitor 214 are included on the path to ground 216.

In the diagram of FIG. 2, the error amplifier 202 has a first input, a second input, and an output. The output of the error amplifier 202 is coupled to an input of the buffer 204. An output of the buffer 204 is coupled to a control terminal of the pass element 206, which in this example is a field effect transistor. A first terminal of the pass element 206 is coupled to Vin and a second terminal is coupled in series to Rload 210 and subsequently to ground 216.

The FFCRR circuitry 208 is in parallel with the pass element 206 by being coupled at one terminal to Vin and the first terminal of the pass element 206, and at a second terminal to the second terminal of the pass element 206 and Vout. Similarly, the series combination of RESR 212 with the load capacitor 214 is in parallel with Rload 210 by being coupled on one end to Vout, and on the other end to ground 216.

The operation of the LDO 108 of FIG. 2 begins with the error amplifier 202. The error amplifier compares a desired output voltage (Vref) to an actual output voltage and generates an error signal as indicative of a comparison between the two voltages. The error signal is used to adjust the difference between the actual output and the Vref, which helps maintain stability and accuracy in the electronic application of the circuit.

Once the error amplifier creates the error signal, the error signal is fed into the buffer 204. The buffer 204 is used to isolate different parts of the circuit from each other so that the driving capability of the circuit is not affected by the load conditions of the connected components. In effect, the buffer 204 helps reduce signal degradation and reduces the impact of impedance mismatch.

After the error signal passes through the buffer 204, the error signal is used as an input to a control gate on the pass element 206. The pass element 206, which in the example of FIG. 2 is a transistor, allows current to flow from a first current terminal, through the transistor, and out a second current terminal when the control gate is enabled (e.g., a signal is sent to the control gate of the pass element 206).

The LDO 108 maintains a stable output voltage by adjusting the pass element 206 to compensate for changes in the voltage source (Vin) and the voltage output (Vout). The dropout voltage, or the minimum voltage difference between the input and output, ensures efficient voltage regulation. The FFCRR 208 acts to cancel out any ripple current seen by fluctuations in the power source providing Vin.

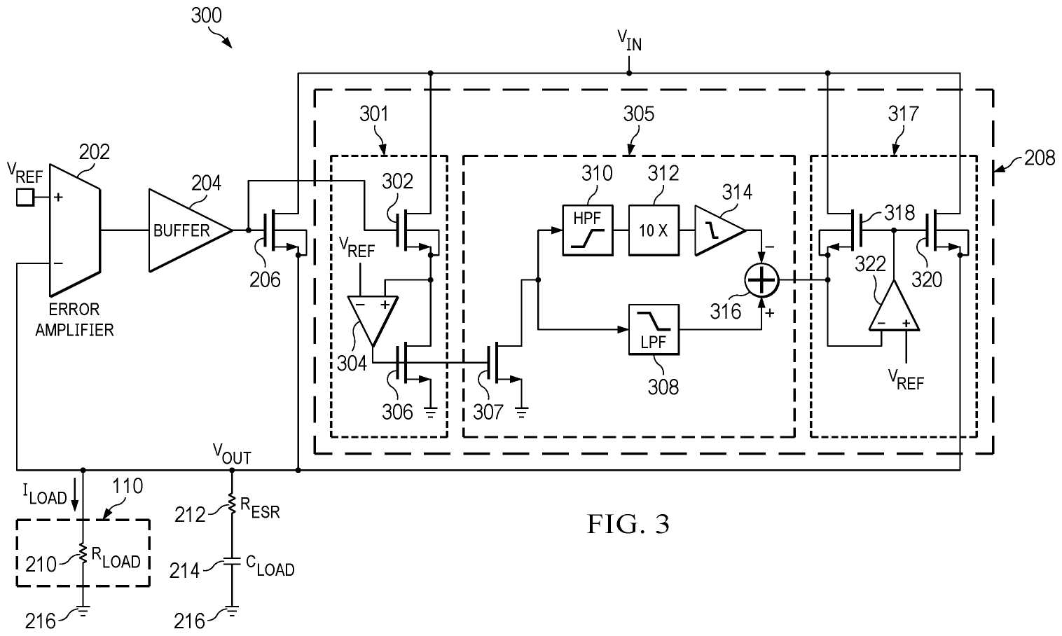

FIG. 3 is a block diagram of an example LDO 300 showing example components of a FFCRR circuitry 208. The LDO 300 of FIG. 3 includes the error amplifier 202, the buffer 204, the pass element 206, the Rload 210, the RESR 212, and the load capacitor 214 of the LDO 108 shown in FIG. 2.

The components of the LDO with a parallel feed-forward current ripple rejection scheme 300 of FIG. 3 can be represented in stages: current sensing 301, sensed current modifying 305, and current canceling 317. The stages can be combined and attached to the LDO circuit 108. Thus, the stages may also be referred to as circuits: a current sensing circuit 301; a current modifying circuit 305; and a current canceling circuit 317.

The LDO 300 of FIG. 3 also includes an example of the FFCRR 208 of FIG. 2. The FFCRR 208 includes a sense element 302, a sensing amplifier 304, a first transistor 306, a second transistor 307, a low pass filter 308, a high pass filter 310, an amplifier 312, a negative gain amplifier 314, an adder 316, a third transistor 318, a fourth transistor 320, and a canceling amplifier 322.

The current sensing stage 301 includes a sensing transistor 302, a sensing amplifier 304 (also known as an operational transconductance amplifier), and a first transistor 306. A control terminal of the sensing transistor 302 is coupled to the control terminal of the pass element 206 of the LDO 300 to create a parallel pathway between Vin and ground. A first current terminal of the sensing transistor 302 is coupled to Vin, and the second current terminal of the sensing transistor 302 is coupled to a first terminal of the first transistor 306 and a first input of the sensing amplifier 304. A second terminal of the sensing amplifier 304 is coupled to a reference voltage (Vref). An output of the sensing amplifier 304 is coupled to a control terminal of the first transistor 306. A second current terminal of the first transistor 306 is coupled to the ground. In the example of FIG. 3, the sensing transistor 302 has a bulk terminal (not shown) that is connected to the second current terminal of the sensing transistor 302. In other examples, the bulk terminal of the sensing transistor 302 may be connected to ground. In the example of FIG. 3, the first transistor 306 has a bulk terminal that is connected to ground. In other examples, the bulk terminal of the first transistor 306 may be connected to the second current terminal of the first transistor 306, which is coupled to the ground.

In operation, the sensing stage acts to sense the current passing through the pass element 206. The sensing amplifier 304 and the first transistor 306 form a negative feedback loop, which in operation causes the voltage at the second current terminal of the sensing transistor 302 equal to the Vref. The Vref is set to be equal to the Vout. Accordingly, the voltage of the second current terminal of pass element 206 equals the voltage of the second current terminal of the sensing transistor 302. The size ratio between the pass element 206 and the sensing transistor 302 is set and defined as K to 1, which causes a reduced amount of current (1/K) to be copied to the current sensing circuit 301.

Current flows through the first current terminal of the sensing transistor 302 and passes through to the second current terminal as controlled by the control terminal of the sensing transistor 302. For example, when the control terminal of the pass element 206 is active, the control terminal of the sensing transistor 302 is also active. If there is a voltage error between the second current terminal of sensing transistor 302 and the Vref, the sensing amplifier 304 functions to eliminate this voltage error by changing the voltage at the control terminal of the first transistor 306. Then, the current flows through the first transistor 306, which eliminates the voltage error. Accordingly, the sensed current (1/K) flows from Vin through the sensing transistor 302 and the first transistor 306 to the ground. The sensed amount of current (1/K) is copied from the first transistor 306 to the second transistor 307 and further processed in the current modifying stage 305.

The sensed current modifying stage 305 includes a second transistor 307, a low pass filter 308, a high pass filter 310, an amplifier 312, a negative gain amplifier 314, and an adder 316. The second transistor 307 has a control terminal that is coupled to the output of the sensing amplifier 304 and in parallel with the control terminal of the first transistor 306 of the sensing stage 301. The second transistor 307 includes a first current terminal coupled to two signal pathways in parallel with each other, and a second current terminal coupled to the ground. The first signal pathway includes a low pass filter 308 that has an input coupled to the first current terminal of the second transistor 307. The low pass filter 308 has an output coupled to a first input of the adder 316. In the second signal pathway, the high pass filter 310 has an input coupled to the first current terminal of the second transistor 307. Also, the high pass filter 310 has an output coupled to an input of the amplifier 312. The amplifier 312 also has an output connected to an input of the negative gain amplifier 314. The negative gain amplifier 314 has an output coupled to a second input of the adder 316.

The low pass filter 308 is a sub-circuit that allows signals with frequencies below a certain cutoff frequency to pass through while attenuating signals that are above the cutoff frequency. The low pass filter acts as a frequency-dependent gate, letting lower-frequency components of a signal pass while filtering out the higher-frequency elements. In the context of FIG. 3, the low pass filter allows a biasing current to pass through, or in other words, allows the constant supplied signal, the sensed current, to pass while attenuating the rapid, sensed fluctuations in the signal known as ripple current.

The high pass filter 310 is a sub-circuit designed to allow signals with frequencies above a certain cutoff frequency to pass through while attenuating signals below the cutoff frequency. The high pass filter 310 permits the higher-frequency components of a signal to pass through while filtering out the lower-frequency components of a signal. In the context of FIG. 3, the higher frequency components of the signal input to the high pass filter are the copy of the ripple current that are fluctuating from the biasing signal.

The amplifier 312 is an amplification component that increases the strength or amplitude of an input signal by a factor. In the example of FIG. 3, a gain of ten is associated with the amplifier 312. A signal that is input into the amplifier 312 will be increased by a factor of ten and subsequently output. The greater amplitude signal subsequently has sufficient strength for effective transmission and processing without distortion.

The negative gain amplifier 314, which may also be known as an inverting amplifier, is a sub-circuit or component that takes an input signal and produces an output signal with an amplitude that is inverted and scaled relative to the input signal. In other words, the negative gain amplifier 314 introduces a phase shift of the input signal (e.g., approximately 180 degrees out of phase with sensed current ripple). The negative gain is then achieved by employing an inverting operational amplifier configuration, where the input signal is connected to the inverting terminal. The result is a positive signal that is input into the negative gain amplifier 314 has a negative signal output, and a negative signal that is input into the negative gain amplifier 314 has a positive signal output. In both instances, the magnitude of the input and the magnitude of the output are the equivalent.

In operation, the sensed current modifying stage modifies the sensed current to create a signal that can cancel out the current ripple generated from the Vin source. This is performed by passing the sensed and copied signal from the sensing stage through both high pass and low pass filters in parallel. The passing of the sensed and copied signal through the low pass filter 308 allows for the low frequency signal to pass through while attenuating the high frequency signal. In doing so, the baseline or biasing signal is propagated to the next stage to establish an operating point for further signal processing. The passing of the sensed and copied signal through the high pass filter 310 and subsequently the amplifier 312 and the negative gain amplifier 314 allows for the high frequency signal to pass through while attenuating the low frequency signal. In doing so, the periodic signal fluctuations (current ripple) are captured. These periodic signal fluctuations are subsequently amplified and inverted for later cancelation. Both pathways are added together for the subsequent signal processing of the canceling stage.

The current canceling stage 317 includes a third transistor 318, a canceling transistor 320, and a canceling amplifier 322. The third transistor 318, also known as a feedback transistor, has a first current terminal, a second current terminal, and a control terminal. The first current terminal is coupled to Vin. The second current terminal is coupled to a first input terminal of the canceling amplifier 322 and the output of the adder 316 from the current modifying stage. The control terminal of the third transistor 318 is coupled to the output of the canceling amplifier 322, as well as a control terminal of the canceling transistor 320. The second current terminal of the canceling transistor 320 is connected to an output of the example apparatus, which is an LDO in the example of FIG. 3. A first current terminal of the canceling transistor is coupled to Vin, and the second current terminal of the canceling transistor 320 is coupled to Vout. Also, the second input of the canceling amplifier 322 is coupled to a reference voltage, Vref.

The canceling amplifier 322 acts to reduce unwanted signals or noise from its output. The canceling amplifier 322 employs a feedback mechanism that senses the undesired signal by having the signal input at a first terminal. This input is compared to the desired signal (Vref) input at a second terminal of the canceling amplifier 322. Accordingly, an opposing signal to the undesired signal is produced at Vout.

The second current terminal of the third transistor 318 is equal to Vref due to the feedback mechanism formed by the third transistor 318 and the canceling amplifier 322. The control terminal of the third transistor 318 is controlled by the output of the canceling amplifier 322. The output of the canceling amplifier 322 causes the current in the third transistor 318 to be equal to the current at the output of the adder 316 from the current modifying stage by controlling current to flow from Vin through the third transistor 318 when the control terminal of the third transistor 318 is controlled by the output of the canceling amplifier 322.

The first current terminal of the canceling transistor 320 and the first current terminal of the third transistor 318 are coupled to Vin. The control terminal of the canceling transistor 320 and the control terminal of the third transistor are coupled to each other. The feedback mechanism formed by the third transistor 318 and the canceling amplifier 322 causes the second current terminal of the third transistor 318 to be equal to the Vref voltage. The Vref voltage equals the Vout voltage. Accordingly, the voltage of the second current terminal of the third transistor 318 equals the voltage of the second current terminal of the canceling transistor 320.

The ratio of current flow through the third transistor 318 to the current flow through the canceling transistor 320 is determined by the ratio of size between the third transistor 318 and the size of the canceling transistor 320. In the example of FIG. 3, the size of the canceling transistor 320 is K/10 times the size of the third transistor 318. The ripple current flowing through the canceling transistor 320 is K/10 times the ripple current in the third transistor 318. Accordingly, the magnitude of the ripple current flowing through canceling transistor 320 equals the ripple current in pass element 206.

In operation, the canceling stage operates to inject the modified sensed current to the Vout node. The signal that is sensed and subsequently modified is introduced to Vout through the usage of the canceling amplifier 322, the third transistor 318 and the canceling transistor 320. The output of the canceling amplifier 322 controls the control terminals of the third transistor 318 and the canceling transistor 320, which in turn controls the current flow through the third transistor 318 and the canceling transistor 320. The canceling transistor 320 allows current to flow from Vin, through the canceling transistor 320, and to Vout as determined by the third transistor 318 because the third transistor 318 forms a feedback mechanism with the canceling amplifier 322 to take in the output current of the adder, then control the current flow through the canceling transistor 320 by modifying the voltage at the control terminal of the canceling transistor 320.

In the operation of the LDO with a parallel feed-forward current ripple rejection scheme 300, the stages operate together to cancel out the change in current through the pass element 206. This is done by transmitting a current opposite of the change in current due to noise (cancelation current) through the pass element 206. The cancelation current is generated by use of the FFCRR 208, which senses the amount of current fluctuating through the pass element 206, copies the current fluctuations, modifies the current fluctuation by filtering, inverting, and amplifying the signal. The generated cancelation current is then introduced to the Vout node to cancel out the change in current through the pass element 206.

The relationships of the transconductance of the transistors and gain of the amplifier are interrelated. For any amount of current through the pass element 206, the sensing stage senses a ratio of current, K:1. The gain of the amplifier 312 in the current modifying stage can be selected. The amount of current allowed through the third transistor 318 must be equal to the amount of current through the sensing transistor 302. Accordingly, the canceling transistor 320 must have a transconductance of K over the strength of the amplifier.

In the example of FIG. 3, the pass element 206 is a pass transistor with a transconductance of K. The sensing transistor 302 has a transconductance of 1 and effectively steps down the amount of current by K:1. The amplifier 312 can be chosen to have a gain, G, which, in the example of FIG. 3, is ten. The third transistor (the feedback transistor) 318 has a transconductance equal to that of the sensing transistor 302 (e.g., 1) in order to enable a current flow through the third transistor 318 equal to the current at the output of the adder 316. The current flow is controlled by the output of the canceling amplifier 322, which forms a feedback loop with the third transistor 318. The formation of the feedback loop in combination with controlling the current flow through the third transistor 318 to be equal to the current output of the adder 316 causes the feedback mechanism of the canceling amplifier 322 to be the control for the canceling transistor 320. The canceling transistor 320 then has a transconductance of K/G, which, in the example of FIG. 3, is K/10.

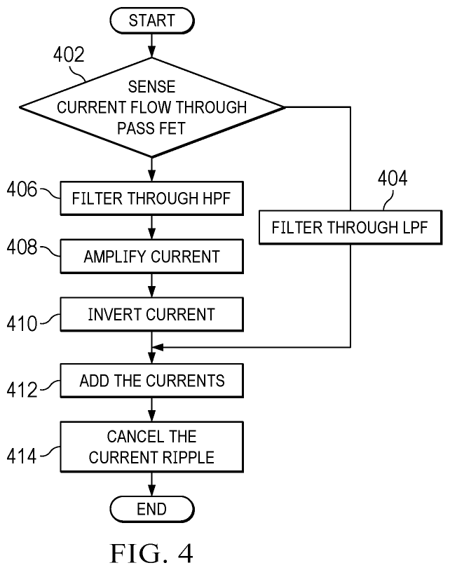

FIG. 4 is a flowchart demonstrating the functionality of a feed-forward current ripple rejection circuitry. The process starts at block 402, where the sensing stage senses current flow through the pass element 206. For example, the ripple current in the pass element 206 is quantified as A. The sensing stage senses the current flow through the pass element 206 and copies the ripple current to the sensing transistor 302 at a value of A/K.

After the current is sensed through the pass element 206, parallel pathways allow for the current to be modified. In the first pathway shown by block 404, the current is filtered by a low pass filter. The low pass filter allows the low frequency signals to pass through while attenuating high frequency signals. This filters out the unwanted noise, signals, and fluctuations in the input signal and allows only for the certain lower-frequency component to be transmitted to bias the next stage.

In the second pathway shown after sensing the current flow through the pass element 206 of FIG. 4, block 406 shows the signal is filtered through a high pass filter. The high pass filter allows high frequency signals to be transmitted while attenuating the low frequency signals. This allows for passing of the fluctuations in the input signal while filtering out the undesired lower frequency signals. The fluctuations in the input signal are subsequently modified by being amplified in block 408, and subsequently inverted in block 410. The amplification of the signal and subsequent inversion allow for the captured current ripple, which is largely passed through the pass element 206, to be magnified for further signal processing.

Once the input signal is sensed at 402, biased through block 404, as well as filtered and modified through blocks 406, 408, and 410, the two processed signal components are added together by the adder 316 in block 412. The combination of a bias signal and the inverted copy of the ripple current allow for subsequent injection of the signal for cancelation of the current ripple.

The subsequent injection of the signal for cancelation of the current ripple happens at block 414, where the canceling stage of the LDO with a parallel feed-forward current ripple rejection scheme 300 uses a canceling element 320 to inject the signal to Vout, where the ripple current is canceled. The Vout of the LDO can then be used as an input to an Rload 210, which is shown in FIG. 1 to be a processor circuitry 110.

As used herein, the term “transistors” has been used as an open-ended term to include field-effect transistors (FETs), or transistors of any other technology. The term transistors is to be construed as a semiconductor device used for electronic switching and amplification, regardless of structure or operational differences. Even though some transistors utilize bipolar junctions and carriers and some transistors (e.g., FETs) rely on electric fields to control current flow, both implementations are intended.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is not feasible and/or advantageous.

In this description, the term “and/or” (when used in a form such as A, B and/or C) refers to any combination or subset of A, B, C, such as: (a) A alone; (b) B alone; (c) C alone; (d) A with B; (c) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first”, “second”, “third”, etc. are used merely to distinguish between elements of substantially the same type in terms of structure and/or function. These identifiers, as used in the detailed description, do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin”, and “lead” are used interchangeably. Unless specifically stated to the contrary, these terms are generally used to mean an interconnection between or a terminus of a device element, a circuit element, an integrated circuit, a device or other electronics or semiconductor component.

A circuit or device which is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described examples, and other examples are possible, within the scope of the claims.

From the foregoing, it will be appreciated that example systems, apparatus, articles of manufacture, and methods have been described that prevent common-mode propagation and lock-up for frequency divider circuits. Described systems, apparatus, articles of manufacture, and methods improve the efficiency of using a computing device by improving stability, reducing output voltage variation, and reducing the impact of load changes in low dropout regulators. This leads to a more reliable and consistent power supply, especially in applications where a stable voltage is advantageous. Described systems, apparatus, articles of manufacture, and methods are accordingly directed to one or more improvement(s) in the operation of a machine such as a computer or other electronic and/or mechanical device.

The following claims are hereby incorporated into this Detailed Description by this reference. Although certain example systems, apparatus, articles of manufacture, and methods have been described herein, the scope of coverage of this patent is not limited thereto. On the contrary, this patent covers all systems, apparatus, articles of manufacture, and methods fairly falling within the scope of the claims of this patent.

What is claimed is:

1. A circuit comprising:
a first transistor having a first current terminal, a control terminal, and a second current terminal, the second current terminal of the first transistor coupled to a ground terminal;
a low-pass filter having an input and an output, the input of the low-pass filter coupled to the first current terminal of the first transistor;
a high-pass filter having an input and an output, the input of the high-pass filter coupled to the first current terminal of the first transistor;
a first amplifier having an input and an output, the input of the first amplifier coupled to the output of the high-pass filter;
a negative gain amplifier having an input and an output, the input of the negative gain amplifier coupled to the output of the first amplifier;
an adder having a first input, a second input, and an output, the first input of the adder coupled to the output of the negative gain amplifier, the second input coupled to the output of the low-pass filter;
a second amplifier having a first input, a second input and an output, the first input coupled to the output of the adder;
a second transistor having a first current terminal, a control terminal, and a second current terminal, the control terminal of the second transistor coupled to the output of the second amplifier, the second current terminal of the second transistor coupled to the first input of the second amplifier; and
a third transistor having a first current terminal, a control terminal, and a second current terminal, the control terminal of the third transistor coupled to the output of the second amplifier, the second current terminal of the third transistor coupled to an output terminal.

2. The circuit of claim 1, wherein:
the second transistor has a bulk terminal, the bulk terminal of the second transistor coupled to the second current terminal of the second transistor.

3. The circuit of claim 1, wherein the third transistor has a bulk terminal, the bulk terminal of the third transistor coupled to the second current terminal of the third transistor.

4. The circuit of claim 1, further including a current sensing circuit, the current sensing circuit including:
a fourth transistor having a first current terminal, a control terminal, a bulk terminal and a second current terminal, the bulk terminal coupled to the second current terminal of the fourth transistor;
a third amplifier having a first input, a second input, and an output, the second input coupled to the second current terminal of the fourth transistor; and
a fifth transistor having a first current terminal, a control terminal and a second current terminal, the first current terminal of the fifth transistor coupled to the second current terminal of the fourth transistor, the control terminal coupled to the output of the third amplifier.

5. The circuit of claim 4, wherein the control terminal of the first transistor is coupled to the control terminal of the fifth transistor.

6. The circuit of claim 4, wherein the third amplifier is an operational transconductance amplifier.

7. The circuit of claim 4, further including a sixth transistor having a first current terminal, a control terminal and a second current terminal, the second current terminal of the sixth transistor coupled to the output terminal, the control terminal of the sixth transistor coupled to the control terminal of the fourth transistor.

8. The circuit of claim 7, wherein the sixth transistor has a bulk terminal, the bulk terminal of the sixth transistor coupled to the second current terminal of the sixth transistor.

9. The circuit of claim 7, wherein:
the fourth transistor is configured to sense a first current in the sixth transistor; and
the fourth transistor having a second current is stepped down by a first ratio.

10. The circuit of claim 9, wherein:
the second transistor has a third current, the third current configured to be related to a fluctuation in the second current multiplied by a gain associated with the first amplifier.

11. The circuit of claim 10, wherein the third transistor has a fourth current stepped up by the first ratio divided by the gain associated with the first amplifier.

12. The circuit of claim 1, wherein the first transistor, second transistor, and third transistor are field-effect transistors.

13. The circuit of claim 1, wherein the control terminal of the first transistor is coupled to a current sensing circuit.

14. The circuit of claim 1, wherein:
the second input of the second amplifier is coupled to a first voltage source;
the first current terminal of the second transistor is coupled to a second voltage source; and
the first current terminal of the third transistor is coupled to the second voltage source.

15. A low dropout regulator circuit comprising:
an error amplifier having a first input, a second input, and an output, the first input coupled to a reference voltage, the second input coupled to an output of the low dropout regulator;
a buffer having an input and an output, the input of the buffer coupled to the output of the error amplifier;
a pass transistor having a control terminal, a first current terminal, and a second current terminal, the control terminal coupled to the output of the buffer, the second current terminal coupled to the output of the low dropout regulator; and
a feed forward current ripple rejection circuit having an input and an output, the input of the feed forward current ripple rejection circuit coupled to the first current terminal of the pass transistor, the output of the feed forward current ripple rejection circuit coupled to the output of the low dropout regulator.

16. The low dropout regulator circuit of claim 15, wherein the feed forward current ripple rejection circuit includes:
a current sensing stage including a sensing transistor;
a sensed current modifying stage including an amplifier; and
a current canceling stage including:
a feedback transistor; and
a canceling transistor.

17. The low dropout regulator circuit of claim 16, wherein:
the sensing transistor having a first current terminal, a control terminal, a bulk terminal and a second current terminal, the control terminal of the sensing transistor coupled to the control terminal of the pass transistor; and
the canceling transistor having a first current terminal, a control terminal, and a second current terminal, the second current terminal of the canceling transistor coupled to the output of the low dropout regulator.

18. The low dropout regulator circuit of claim 17, wherein:
a transconductance of the feedback transistor is equal to a transconductance of the sensing transistor; and
a transconductance of the canceling transistor is equal to a transconductance of the pass transistor divided by a gain of the amplifier.

19. A low dropout regulator circuit comprising:
an error amplifier configured to generate an error signal of a comparison of an output voltage to a reference voltage;
a buffer configured to stabilize the output voltage;
a pass transistor configured to control a flow of current through the pass transistor; and
a feed forward current ripple rejection circuit in parallel with the pass transistor, the feed forward current ripple rejection circuit including:
a sensing transistor configured to sense the current passing through the pass transistor;
an amplifier having a gain, the amplifier configured to amplify a signal for further processing, the signal indicative of current ripple through the pass transistor;
a feedback transistor configured to form a feedback loop with a canceling amplifier, wherein a first current terminal of the feedback transistor has a voltage equal to the reference voltage; and
a canceling transistor configured to inject the signal indicative of current ripple into an output of the low dropout regulator circuit, the signal indicative of current ripple 180 degrees out of phase with a sensed current ripple.

20. The low dropout regulator circuit of claim 19, wherein:
a transconductance of the pass transistor is K;
the gain of the amplifier is G; and
a transconductance of the canceling transistor is K/G.
